(19) United States
(12) Patent Application Publication
(10) Pub. No.: US 2006/0113143 A1
(43) Pub. Date: Jun. 1, 2006

(54) Acoustic device

(75) Inventor: Yuuji Ishida, Kanagawa (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 11/256,504

(22) Filed: Oct. 21, 2005

(30) Foreign Application Priority Data
Nov. 29, 2004 (JP) 2004-345020

(51) Int. Cl. H05K 5/00

(52) U.S. Cl. 181/148

(57) ABSTRACT

An acoustic device able to provide sounds showing a stereo effect even if a housing is small in size, wherein, inside a first surface of a second housing, each of sound guiding spaces (sound resonance spaces) for the respective speakers is defined by a sound outputting surface of the speaker, a front surface side case, and an inner wall formed between the sound outputting surface of the speaker and the front surface side case, further, first sound outputting holes outputting sounds in a high frequency sound band and second sound outputting holes outputting sounds in an intermediate frequency sound band and in a low frequency sound band are provided so as to communicate with the respective sound guiding spaces (sound resonance spaces).

### BACKGROUND OF THE INVENTION

1. Field of the Invention

The present invention relates to an acoustic device such as a portable telephone (a cellular phone or a mobile phone), a personal digital assistant (PDA), or a digital camera, in which two speakers are built-in and able to provide a stereo sound.

2. Description of the Related Art

Japanese Unexamined Patent Publication (Kokai) No. 2004-32352, for example, discloses a portable electric apparatus such as a cellular phone, a PDA, or a digital camera, in which two speakers are provided and each speaker outputs an independent sound to result in a stereo sound.

However, since a housing of such the portable electric apparatus is formed small for realizing a reduction of a size, the two speakers are closely arranged in the housing, and sound outputting holes for the speakers are also closely arranged, it suffers from the disadvantages that acoustic interference, particularly in a high frequency sound band may easily occur and it would be hard to provide the stereo sound.

### SUMMARY OF THE INVENTION

An object of the present invention is to provide an acoustic device able to output sounds obtaining a stereo effect with small or less acoustic interference in a high frequency sound band even if a housing is small in size.

According to a first aspect of the present invention, there is provided an acoustic device having: a housing; two sound outputting means placed in the housing; two sound guiding spaces formed in the housing and corresponding to the two sound outputting means; two first sound outputting holes formed in a first surface of the housing and connecting with the sound guiding spaces; and second sound outputting holes formed in other surfaces different from the first surface of the housing and connecting with the sound guiding spaces. And, the sound resonance frequency of the second sound outputting holes is lower than that of the first sound outputting holes.

According to a second aspect of the present invention, there is provided an acoustic device having: a first housing including an operation unit; a second housing; and a coupling unit coupling the first housing and the second housing. And, the second housing has a display unit, two sound outputting means placed inside the housing, two sound guiding spaces formed in the housing and corresponding to the two sound outputting means, two first sound outputting holes formed in a first surface of the housing and connecting with the sound guiding spaces, and second sound outputting holes formed in other surfaces different from the first surface of the housing and connecting with the sound guiding spaces. Further, the sound resonance frequency of the second sound outputting holes is lower than that of the first sound outputting holes.

Preferably, the display unit is placed in the first surface of the housing, other surfaces thereof are two side surfaces adjoining to the first surface, and the second sound outputting holes are respectively formed in the two side surfaces.

Preferably, the first surface of the housing is formed with a rectangle shape and the first sound outputting holes are arranged in parallel in a short length direction of the first surface.

According to the present invention, the acoustic interference can be lowered to output the sound having the stereo effect.

### BRIEF DESCRIPTION OF THE DRAWINGS

The above and other features of embodiments of the present invention will be apparent in more detail with reference to the accompanying drawings, in which:

FIG. 1 is a perspective view of an outer shape in an open state of a cellular phone of an embodiment according to the present invention;

FIG. 2 is a perspective view of an outer shape in a closed state of the cellular phone in FIG. 1;

FIGS. 3A to 3C are views for explaining a sound output structure of the cellular phone according to the present embodiment, wherein FIG. 3A is a front view of the cellular phone of FIG. 1; FIG. 3B is a side view thereof; and FIG. 3C is a simplified cross-sectional view of the sound output structure of a second housing;

FIG. 4 is a graph showing frequency characteristics in the case of only forming second sound outputting holes and in the case of forming the second sound outputting holes and additionally first sound outputting holes; and

FIG. 5A is a graph showing an acoustic sound diffusion characteristic in the case where only the second sound outputting holes are provided, and FIG. 5B is a graph showing the acoustic sound diffusion characteristic in the case where the second sound outputting holes and additionally the first sound outputting holes are provided.

### DESCRIPTION OF THE PREFERRED EMBODIMENTS

Preferred embodiments of the present invention will be described with reference to the accompanying drawings.

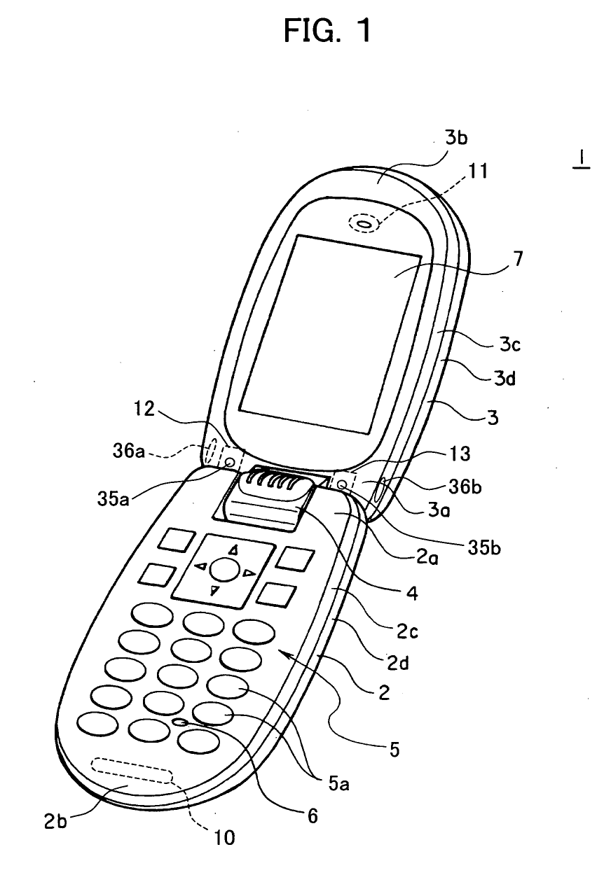

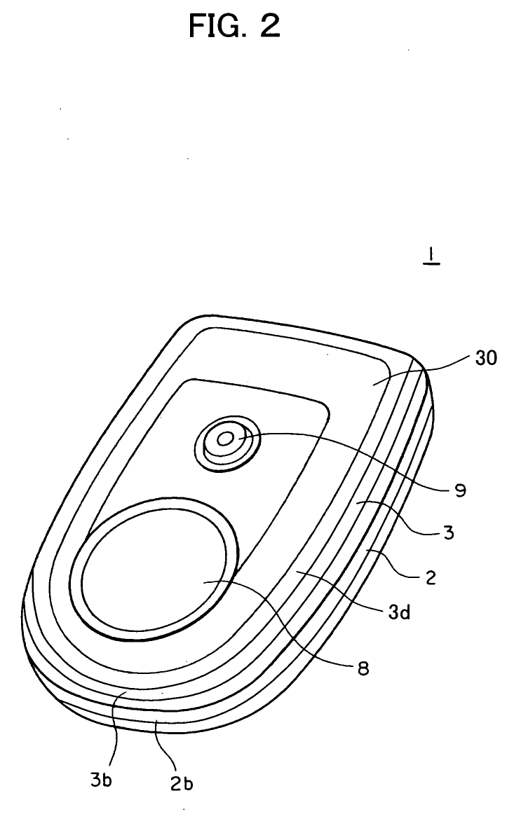

FIG. 1 and FIG. 2 are perspective views of an outer shape of an embodiment of a cellular phone as an example of an acoustic device according to the present invention. FIG. 1 shows an open state of the cellular phone and FIG. 2 shows a closed state thereof.

A cellular phone 1 is provided with a first housing 2 and a second housing 3. An end portion 2a of the first housing 2 and an end portion 3a of the second housing 3 are rotably coupled by a coupling unit (hinge unit) 4 to be the both housings openable and closable.

The first housing 2 and the second housing 3 are respectively provided with front surface side cases 2c and 3c at a surface (front surface) side opposed each other in the closed state, and back surface side cases 2d and 3d at its back surface side. Those front surface side cases 2c and 3c are formed so as to almost match contours of the opposed surfaces in looking at one housing side from another housing side in the closed state, and the end portions 2b and 3b (openable and closable side) which are different from the end portions coupled with the first housing 2 and the second housing 3 are matched in the closed state.

The first housing 2 has an operation unit 5 in its front surface. In the operation unit 5, ten-key bottoms 5a or other buttons (pressing unit) for operating the cellular phone 1 are arranged. Also, in the operation unit 5, an opening portion 6 for collecting a sound is provided in a region where the ten-key bottoms 5a are arranged. Note that, the opening portion 6 may be provided with a protective film to prevent the enter of dust and other particles into the first housing 2.

The second housing 3 is provided with a main display unit (first display unit) 7 for displaying an image at a front surface (first surface) 31 and a sub display unit (second display unit) 8 for displaying another image at its back surface 30 in the respective surfaces. An opening window in the back surface side case 3d for exposing the sub display unit 8 is formed with a circular shape. The main display unit 7 and the sub display unit 8 are formed by, for example, a transparent type or reflectance type liquid crystal display. Note that, as the display, an organic electro luminance display or other display devices may be applied.

At the back surface 32 of the second housing 3, a pressing button (pressing unit) 9 for instructing an operation of the sub display unit 8 is placed. The pressed button 9 is made of, for example, resin or hard rubber and is movably placed in a vertical direction to a surface placed the sub display unit 8 of the back surface side case 3d.

Further, in the openable and closable cellular phone 1 according to the present embodiment, a transmitting and receiving antenna 10 is built into the end portion 2b side of the first housing 2 and a speaker 11 is built into the end portion 3b of the second housing 3. In the case where the first housing 2 and the second housing 3 are in the closed state as shown in FIG. 2, the antenna 10 is arranged to adjacently oppose to the speaker 11 arranged in the end portion 3b of the second housing 3. Conversely, in the open state, the antenna 10 is separately arranged from the speaker 11 as shown in FIG. 2.

In the present embodiment, two speakers 12 and 13 functioning as sound outputting units (means) for providing the stereo effect are built into and arranged in parallel in a short length direction of the second housing 3 with a rectangle shape in the vicinity of a lower edge portion of the main display unit 7 in FIG. 1.

In the present embodiment, even if the two speakers 12 and 13 are closely placed, a structure outputting the sound, showing the stereo effect by which an acoustic interference difficulty occurs in a high frequency sound band, is applied.

Hereinafter, this sound output structure unit will be described in detail.

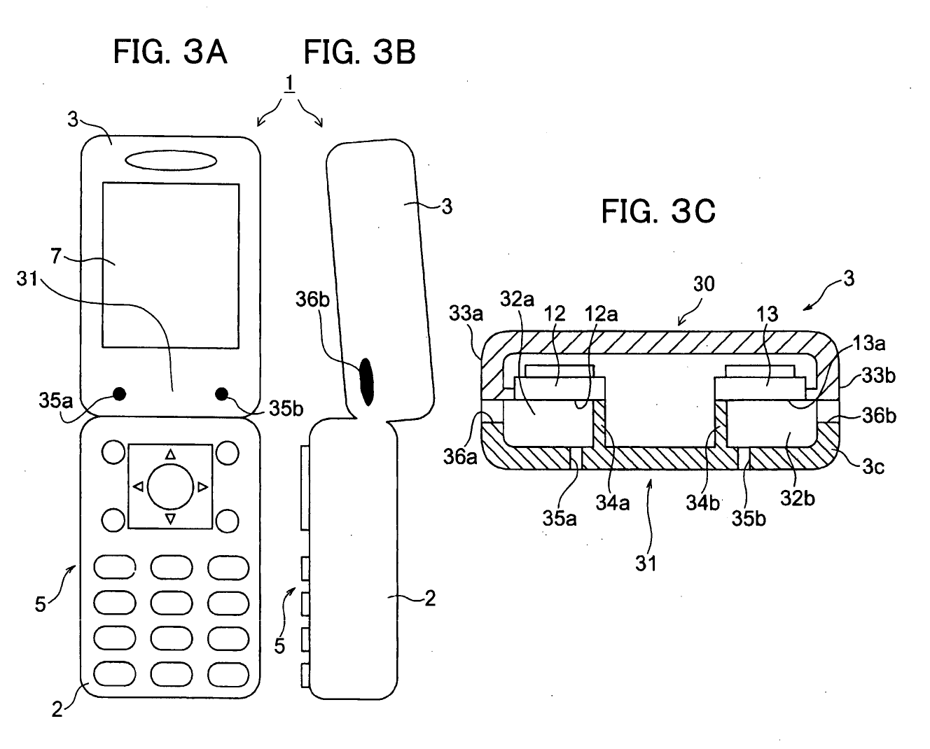

FIGS. 3A to 3C are views for explaining the sound output structure of the cellular phone 1 according to the present embodiment. FIG. 3A is a front view of the cellular phone, FIG. 3B is a side view thereof, and FIG. 3C is a simplified cross-sectional view of a sound output structure portion of the second housing 3. Note that, in FIGS. 3A to 3C, the coupling unit is omitted.

As described above, the second housing 3 is provided with the main display unit 7 arranged in the first surface 31 and, inside the lower edge portion of the main display unit 7 as shown in FIG. 3C, the two speakers 12 and 13 separately arranged with a predetermined distance in the short length direction (a horizontal direction in the drawing) of the second housing 3 so as to face them in a thickness direction (a vertical direction in the drawing).

Inside the first surface 31 of the second housing 3, a sound guiding space (sound resonance space) 32a for the speaker 12 is defined by a sound outputting surface 12a of the speaker 12, a front surface side case 3c, and an inner wall 34a formed between the sound outputting surface 12a of the speaker 12 and the front surface side case 3c.

In the same way, inside the first surface 31 of the second housing 3, a sound guiding space (sound resonance space) 32b for the speaker 13 is defined by a sound outputting surface 13a of the speaker 13, a front surface side case 3c, and an inner wall 34b formed between the sound outputting surface 13a of the speaker 13 and the front surface side case 3c.

In the first surface 31 of the second housing 3 in the vicinity of a left end in the drawings of the lower edge portion of the main display unit 7, a first sound outputting hole 35a having a circular shaped section and communicating with the sound guiding space 32a for the speaker 12 is formed. In other side surface 33a different from the first surface 31, a second sound outputting hole 36a with an ellipse shaped section and connecting to the sound guiding space 32a for the speaker 12 is formed.

In the same way, in the first surface 31 of the second housing 3 in the vicinity of a right end in the drawings of the lower edge portion of the main display unit 7, a first sound outputting hole 35b having a circular shaped section and communicating with the sound guiding space 32b for the speaker 13 is formed. In other side surface 33a different from the first surface 31, a second sound outputting hole 36b with an ellipse shaped section and connecting to the sound guiding space 32b for the speaker 13 is formed.

In this way, the first sound outputting holes 35a and 35b are formed in the first surface 31, the second sound outputting hole 36a is formed in one side surface 33a, and the second sound outputting hole 36b is formed in another side surface 33b. Here, those sound resonance frequencies are set to be the sound resonance frequency of the second sound outputting holes 36a and 36b lower than that of the first sound outputting holes 35a and 35b.

Here, the sound resonance frequency of the first sound outputting holes 35a and 35b can be expressed by formula 1 and that of the second sound outputting holes 36a and 36b can be expressed by formula 2.
f₁=c/2π×√(S/V(L+1.3A)) (1)

Where, V indicates a volume of the sound guiding space 32a (or 32b),

A indicates a radius of the first sound outputting hole 35a (or 35b),

L indicates a depth of the first sound outputting hole 35a (or 35b),

S indicates an opening portion area of the first sound outputting hole 35a (or 35b),

c indicates a velocity of sound (approximately 340 m/s at a normal ambient temperature), and

f₁ indicates the sound resonance frequency.
f₂=c/2π×√(T/W(M+1.3B)) (2)

Where, W indicates a volume of the sound guiding space 32a (or 32b),

B indicates a radius of the second sound outputting hole 36a (or 36b),

M indicates a depth of the second sound outputting hole 36a (or 36b),

T indicates an opening portion area of the second sound outputting hole 36a (or 36b),

c indicates a velocity of sound (approximately 340 m/s at a normal ambient temperature), and

f₂ indicates the sound resonance frequency.

In the formulas 1 and 2, in the case where the first sound outputting holes 35a and 35b and the second sound outputting holes 36a and 36b are respectively different shapes, each radius may be calculated by obtaining the opening portion area of each of the holes and assuming the result as a circular shaped area.

As described above, the sound output structure unit of the present embodiment is placed with the built-in two speakers 12 and 13 to oppose the sound outputting surfaces 12a and 13a thereof to the first surface 31 functioning as a surface, placed with the main display unit 7, and to arrange the same in parallel in the short length direction of the second housing 3 to thereby form an acoustic structure unit within a range of a thickness of the second housing 3.

Consequently, by the structure unit, it is preferably to obtain an acoustic characteristic in listening to sounds while viewing the main display unit 7, without change of the thickness of the cellular phone.

The sound guiding spaces (sound resonance spaces) 32a and 32b formed in front of the speakers 12 and 13 respectively communicate with the second sound outputting holes 36a and 36b in a right side surface and a left side surface (the second surfaces) 33a and 33b toward a displaying surface of the main display unit 7, and are formed to enable an output of sounds from a right and left symmetric direction to thereby achieve a so-called stereo channel separation even if the speakers 12 and 13 are closely placed.

To achieve the above effects, it is preferably to set the sound resonance frequency f₁ of the first sound outputting holes 35a and 35b at a range equal to or higher than 6000 Hz and the sound resonance frequency f₂ of the second sound outputting holes 36a and 36b at a range less than 6000 Hz. Consequently, the stereo sound which leads lower acoustic interference in a high frequency sound band can be achieved.

Further, in the case of the folded cellular phone 1, the first sound outputting holes 35a and 35b are opposed to a surface where the operation unit 5 of the first housing 2 is formed, so it is not possible to expect the acoustic effect so much. However, the second sound outputting holes 36a and 36b are outward in the case where the cellular phone 1 is folded, and the surface where the operation unit 5 is formed is positioned to close the sound outputting holes 35a and 35b in front of the two speakers 12 and 13, this makes the stereo channel separation to increase, consequently, an acoustic sound diffusion characteristic to the surrounds is improved (the interference occurs difficulty).

The above features are beneficial for informing or noticing of ringing when receiving a phone call, needed for a fold type cellular phone.

Also, by the first sound outputting holes 35a and 35b and the second sound outputting holes 36a and 36b, acoustic spaces which leads low sound stagnation (sound retention) and stabilization of a sound localization, can be formed.

Further, in the case of carrying the folded cellular phone 1 by a hand(s) for example, it is possible to close the second sound outputting holes 36a and 36b. In this case, however, it is prevented to close the first sound outputting holes 35a and 35b, so it is not suffered from the disadvantage that a ringing of a reception is hardly sounded.

Here, frequency characteristics in the case where only the second sound outputting holes 36a and 36b are provided and in the case where the second outputting holes 36a and 36b and additionally the first sound outputting holes 35a and 35b are provided will be considered.

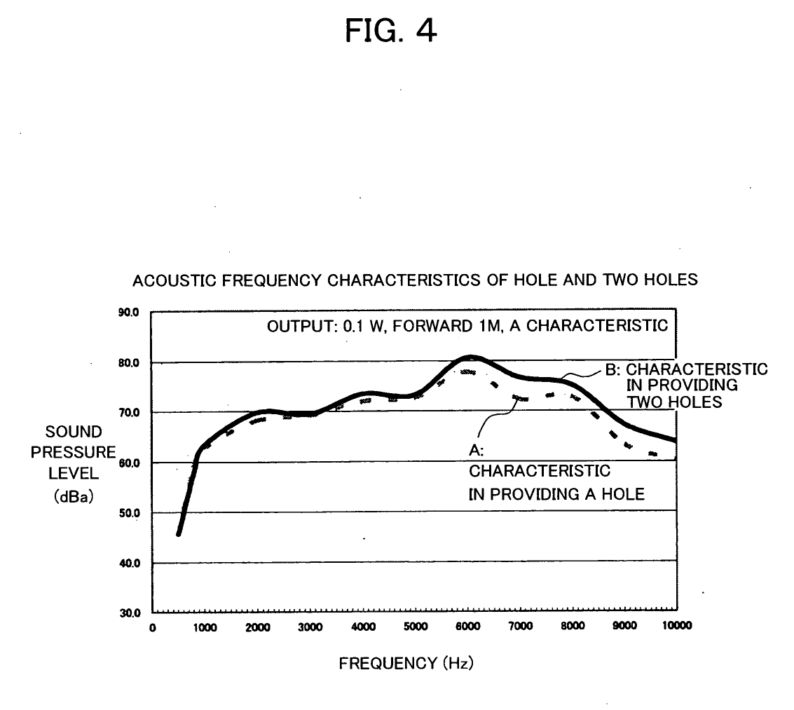

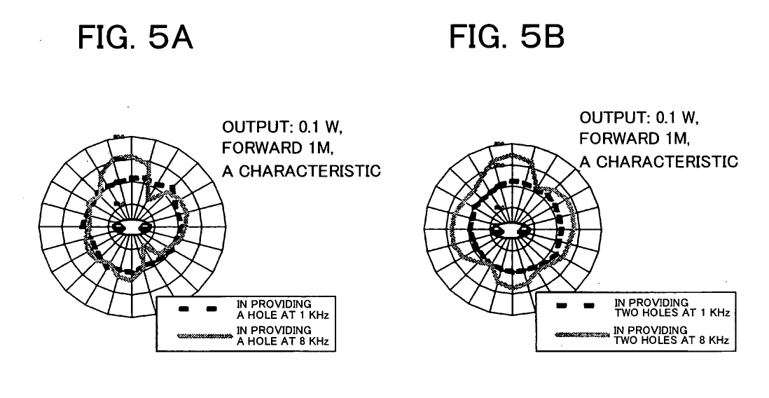

FIG. 4 and FIGS. 5A and 5B are graphs showing results analyzed with a sound, which is collected by a microphone set at a position separated 1 meter from the first surface 31, by an audio analyzer, under the condition where the sound resonance frequency of the first sound outputting holes 35a and 35b is defined as 1 kHz and the sound resonance frequency of the second sound outputting holes 36a and 36b is defined as 8 kHz.

FIG. 4 is a graph showing the frequency characteristics in the case where only the second sound outputting holes 36a and 36b are formed and illustrated by a curve A, and in the case where the first sound outputting holes 35a and 35b and the second sound outputting holes 36a and 36b are formed and illustrated by a curve B.

In FIG. 4, an abscissa indicates the frequency and an ordinate indicates the sound pressure level.

It is understood from the illustration of FIG. 4 that, in the case where the first sound holes 35a and 35b and the second sound holes 36a and 36b are provided, the characteristic in the high frequency sound band equal to or greater than 6 kHz is improved in comparison with the case where only the second sound holes 36a and 36b are provided.

Below, the acoustic sound diffusion characteristics in the case where only the second sound outputting holes 36a and 36b are provided and in the case where the second outputting holes 36a and 36b and additionally the first sound outputting holes 35a and 35b are provided, will be considered.

FIG. 5A shows the acoustic sound diffusion characteristic in the case where only the second sound outputting holes 36a and 36b are provided, and FIG. 5B shows the acoustic sound diffusion characteristic in the case where the first sound outputting holes 35a and 35b and the second outputting holes 36a and 36b are provided.

As shown in FIG. 5A, in the case where only the second sound outputting holes 36a and 36b are provided, the acoustic sound diffusion characteristic in an intermediate frequency sound band (1 kHz) is stabilized, however, the same in the high frequency sound band (8 kHz) has an unstable reception angle (listening angle) due to the interference of a sound wave.

On the other hand, in the case where the first sound outputting holes 35a and 35b and the second outputting holes 36a and 36b are provided, as shown in FIG. 5B, the acoustic sound diffusion characteristic in the intermediate frequency sound band is stabilized similarly to the case where the second sound outputting holes 36a and 36b are provided, and the same in the high frequency sound band is interpolated by the output from the first sound outputting holes 35a and 35b to be improved and stabilized.

As described above, according to the present embodiment, inside the first surface 31 of the second housing 3, the sound guiding space (sound resonance space) 32a for the speaker 12 is defined by the sound outputting surface 12a of the speaker 12, the front side case 3c, and the inner wall 34a formed between the sound outputting surface 12a of the speaker 12 and the front surface side case 3c, and the sound guiding space (sound resonance space) 32b for the speaker 13 is defined by the sound outputting surface 13a of the speaker 13, the front side case 3c, and the inner wall 34b formed between the sound surface 13a of the speaker 13 and the front side case 3c. And additionally, the first sound outputting holes 35a and 35b outputting the sound in the high frequency sound band and the second sound outputting holes 36a and 36b outputting sounds in the intermediate frequency sound band and in a low frequency sound band are provided so as to communicate with the respective sound guiding spaces (sound resonance space) 32a and 32b. Consequently, there are advantages that the acoustic interference in the high frequency sound band can be lowered and the sounds showing the stereo effect can be provided.

Note that, in the case of the structure unit in which the first housing 2 is placed in front of the second housing 3 in viewing them from the front side in the open state, such as the fold type cellular phone according to the present embodiment, as shown in FIG. 1 and FIGS. 3A and 3B, it is preferably that the two speakers 12 and 13 are arranged in the end portion 3a of the second housing 3 and that the first sound outputting holes 35a and 35b are formed at the end portion 3a side in the first surface 31. By forming the structure unit in this way, a sound output from the first sound outputting holes 35a and 35b is provided along an edge surface of the first housing 2 to outside, consequently, sound pressure can be improved.

The present invention is not limited to the cellular phone and may be applied to a PHS, a PDA, a digital camera, a game machine, or other electrical apparatuses. The openable and closable electric apparatus is not limited to the fold type apparatus such as the present embodiment. It may be connected by a coupling (connecting) unit so as to enable housings move respectively between a closed state in which the housings are overlapped each other and an open state in which a part of the opposed portion thereof in the closed state is exposed. Therefore, for example, an apparatus in which a first housing and a second housing are rotated so as to slide the both housings along a surface facing each other, a so-called horizontal rotation type apparatus, may be included.

It should be understood by those skilled in the art that various modifications, combinations, sub-combinations and alterations may occur depending on design requirements and other factors in so far as they are within scope of the appeared claims or the equivalents thereof.

What is claimed is:

1. An acoustic device comprising:
a housing;
two sound outputting means placed in the housing;
two sound guiding spaces formed in the housing and corresponding to the two sound outputting means;
two first sound outputting holes formed in a first surface of the housing and connecting with the sound guiding spaces; and
second sound outputting holes formed in other surfaces different from the first surface of the housing and connecting with the sound guiding spaces,
the sound resonance frequency of the second sound outputting holes being lower than that of the first sound outputting holes.

2. An acoustic device as set forth in claim 1, wherein a display unit is placed in the first surface of the housing, other surfaces thereof are two side surfaces adjoining to the first surface, and the second sound outputting holes are respectively formed in the two side surfaces.

3. An acoustic device as set forth in claim 2, wherein the first surface of the housing is formed with a rectangle shape and the first sound outputting holes are arranged in parallel in a short length direction of the first surface.

4. An acoustic device as set forth in claim 1, wherein each of the sound outputting means faces the corresponding sound guiding space.

5. An acoustic device comprising:
a first housing including an operation unit;
a second housing; and
a coupling unit coupling the first housing and the second housing,
wherein the second housing comprises
a display unit,
two sound outputting means placed inside the second housing,
two sound guiding spaces formed in the second housing and corresponding to the two sound outputting means,
two first sound outputting holes formed in a first surface of the second housing and connecting with the sound guiding spaces, and
second sound outputting holes formed in other surfaces different from the first surface of the second housing and connecting with the sound guiding spaces,
the sound resonance frequency of the second sound outputting holes being lower than that of the first sound outputting holes.

6. An acoustic device as set forth in claim 5, wherein the display unit is placed in the first surface of the housing, other surfaces thereof are two side surfaces adjoining to the first surface, and the second sound outputting holes are respectively formed in the two side surfaces.

7. An acoustic device as set forth in claim 6, wherein the first surface of the housing is formed with a rectangle shape and the first sound outputting holes are arranged in parallel in a short length direction of the first surface.

8. An acoustic device as set forth in claim 5, wherein each of the sound outputting means faces the corresponding sound guiding space.
